(19) United States
(12) Patent Application Publication
(10) Pub. No.: US 2025/0316612 A1
(43) Pub. Date: Oct. 9, 2025

(54) TRENCH SHIELDING WITH PHOTOIMAGEABLE DIELECTRIC (PID) MATERIAL

(71) Applicant: QUALCOMM Incorporated, San Diego, CA (US)

(72) Inventors: Heun Gun SHIN, San Diego, CA (US); Jay Scott SALMON, San Diego, CA (US)

(21) Appl. No.: 18/630,712

(22) Filed: Apr. 9, 2024

(51) Int. Cl. H01L 23/552; H01L 23/66

(52) U.S. Cl. CPC H01L 23/552; H01L 23/66; H01L 2223/6616; H01L 2223/6627

(57) ABSTRACT

In an aspect, an integrated circuit (IC) includes a photoimageable dielectric (PID), a transmission line disposed within the PID, and at least one continuous conductive shield disposed within the PID to reduce leakage of a signal transmitted along the transmission line beyond a space defined by at least one continuous conductive shield. In an aspect, the transmission line is a horizontal transmission line, and a first continuous conductive shield is disposed along a first side of the horizontal transmission line and a second continuous conductive shield is disposed along a second side opposite the first side of the horizontal transmission line. In an aspect, the transmission line is a vertical transmission line, and the continuous conductive shield is a cylindrical conductive shield concentric about the vertical transmission line.

### TECHNICAL FIELD

The present disclosure generally relates to an integrated circuit (IC) device, and more particularly, to transmission line shielding in an IC device.

### BACKGROUND

IC technology has achieved great strides in miniaturization of electronic components. Within an IC device, radio frequency (RF) signals, such as microwave or millimeter wave signals, may need to be transmitted and received at various points of a circuit or between different circuits. Examples of such IC devices include radio frequency (RF) ICs, analog ICs, mixed-signal ICs, and system-on-a-chip (SOC) ICs, which may include multiple function blocks, with each function block designed to perform a specific function, such as, for example, a microprocessor function, a graphics processing unit (GPU) function, a communications function (e.g., cellular, Wi-Fi, Bluetooth, or other communications), or the like. In such IC devices, transmission lines have been implemented for the transmission of RF signals.

Various schemes have been devised for fabricating transmission lines in an IC device. In a typical IC device, a transmission line may be an RF signal line in the form of a conductor enclosed within a thermal cure resin, for example. Such an RF signal line may be a horizontal transmission line, that is, substantially parallel to a ground plane. A horizontal transmission line may be implemented as a conductive strip within a thermal cure resin parallel to the ground plane, for example. Alternatively, the RF signal line may be a vertical transmission line substantially perpendicular to a ground plane within a thermal cure resin, for example. Such an RF signal line may be formed by laser drilling or mechanically drilling a via into the thermal cure resin and forming a metal fill in the via, for example.

In order to provide shielding, that is, to prevent undesired signal leakage from the transmission line to other parts of the IC device and to prevent signals from other parts of the IC device from interfering with signal transmission along the transmission line, via shields have been used to provide a limited degree of shielding. For a horizontal transmission line, a plurality of vias may be provided along the sides of the transmission line. For example, two rows of vias may be formed and metal filled along two sides of the transmission line to form via shields. The vias may be formed by laser drilling or mechanical drilling into the thermal cure resin, for example. In some implementations, filled stacked vias may be formed along two sides of the transmission line to provide shielding across multiple metal layers (for example, M1, M2, M3, etc.). Along each side of the transmission line, however, a gap exists between the edges of each pair of adjacent vias, and such a gap is occupied by a thermal cure resin, for example. Thus, shielding of the transmission line is incomplete because RF signals traveling along the transmission line may leak through the gaps between the vias along both sides of the transmission line.

In order to provide shielding for a vertical transmission line, a plurality of vias may be formed and metal filled around the transmission line. For example, four vias, spaced equally apart and equidistant from the center of the transmission line, may be drilled into the thermal cure resin and metal filled to form via shields for the transmission line. The vias may be laser drilled or mechanically drilled, for example. Because gaps exist between adjacent pairs of via shields around the transmission line, shielding of the transmission line is also incomplete as RF signals traveling along the transmission line may leak through these gaps.

Accordingly, there is a need for improved shielding of transmission lines in IC devices and methods of manufacturing the same to address the above-noted issues.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an integrated circuit (IC) includes a photoimageable dielectric (PID); a transmission line disposed within the PID; and at least one continuous conductive shield disposed within the PID, wherein the at least one continuous conductive shield is positioned to reduce leakage of a signal transmitted along the transmission line beyond a space defined by the at least one continuous conductive shield.

In an aspect, a method of manufacturing an integrated circuit (IC) includes forming a transmission line within a photoimageable dielectric (PID); and forming at least one continuous conductive shield within the PID, wherein the at least one continuous conductive shield is positioned to reduce leakage of a signal transmitted along the transmission line beyond a space defined by the at least one continuous conductive shield.

In an aspect, an electronic device includes an integrated circuit (IC) that comprises: a photoimageable dielectric (PID); a transmission line disposed within the PID; and at least one continuous conductive shield disposed within the PID, wherein the at least one continuous conductive shield is positioned to reduce leakage of a signal transmitted along the transmission line beyond a space defined by the at least one continuous conductive shield.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a cross-sectional view of an IC device according to aspects of the disclosure.

FIGS. 2A-2D illustrate planar views of metal layers M1, M2, M3 and M4, respectively, of an IC device according to aspects of the disclosure.

FIGS. 3A-3B illustrate cross-sectional views depicting an example of a conductive shield formed across metal layers.

FIGS. 4A-4B illustrate top and cross-sectional views, respectively, of an IC device having a trench shielded vertical transmission line.

FIG. 5 illustrates a method for manufacturing an IC, according to aspects of the disclosure.

FIG. 6 illustrates a mobile device, according to aspects of the disclosure.

FIG. 7 illustrates various electronic devices that may incorporate IC devices being put into the IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, and the like indicate that the examples provided are not intended to be limited to the precise numerical values or geometric shapes and include normal variations due to, manufacturing tolerances and variations, material variations, and other design considerations.

As noted in the foregoing, various aspects relate generally to an integrated circuit (IC) device that includes one or more transmission lines and trench shielding with a photoimageable dielectric (PID) material to reduce undesired leakage of signals transmitted along the transmission lines into other parts of the IC device and to reduce undesired interference by signals from other parts of the IC device with signal transmission along the transmission line. It will be appreciated that the various aspects disclosed herein reduce leakage of a signal transmitted along the transmission line by providing a continuous surface for electric field (E-field) termination, when compared to the slotted construction created by via caging of conventional designs, thereby resulting in significant reductions in radiated emissions.

In some aspects, the IC device may be a radio frequency (RF) IC device, an analog IC device, a mixed-signal IC device, or a system-on-a-chip (SOC) device, in which high-frequency RF signals, for example, microwave or millimeter wave signals, may travel between different points within the device. In some aspects, the transmission line may be a horizontal transmission line, that is, substantially parallel to a ground plane, and two continuous conductive shields may be formed by trenching on two sides of the transmission line to shield the transmission line. In some aspects, the transmission line may be a vertical transmission line, that is, substantially perpendicular to a ground plane, and a cylindrical conductive shield concentric about the transmission line may be formed by trenching to shield the transmission line.

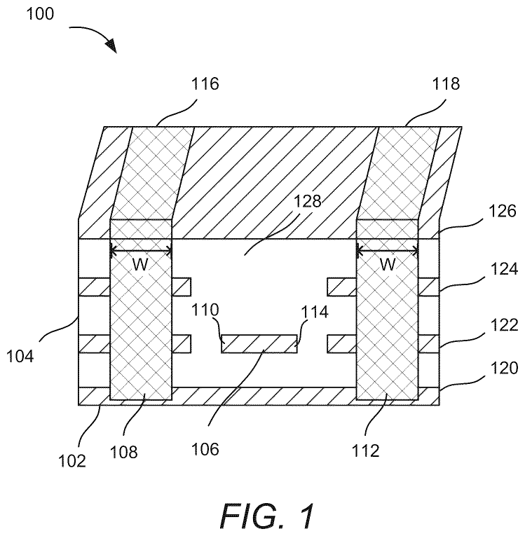

FIG. 1 illustrates a cross-sectional view of an IC device 100, according to aspects of the disclosure. In some aspects, FIG. 1 is a simplified cross-sectional view of the IC device 100, and certain details and components of the IC device 100 may be simplified or omitted in FIG. 1.

In an aspect, the IC device 100 in FIG. 1 may include a ground plane 102. In an aspect, the ground plane 102 may be a metal layer, such as an M1 layer. In some aspects, the ground plane 102 may be another metal layer, such as M2, M3, or another metal layer. In an aspect, a dielectric such as a photoimageable dielectric (PID) 104 may be provided on the ground plane 102. In some aspects, the PID 104 allows trenches to be formed within the PID material without having to use typical drilling methods such as laser drilling or mechanical drilling, for example.

In an aspect, the IC device 100 in FIG. 1 may include a transmission line 106 disposed within the PID 104. In an aspect, the transmission line 106 may be a horizontal transmission line, that is, substantially parallel to the ground plane 102, along the length of the transmission line 106. In an aspect, the transmission line 106 may be in the form of a conductive strip, for example, a metal strip. In an aspect, the transmission line 106 may be a copper strip, although other metals or conductive materials may also be used. In an aspect, the transmission line 106 may have a substantially rectangular cross section, as depicted in FIG. 1, although transmission lines of other cross-sectional geometries may also be implemented in the PID 104.

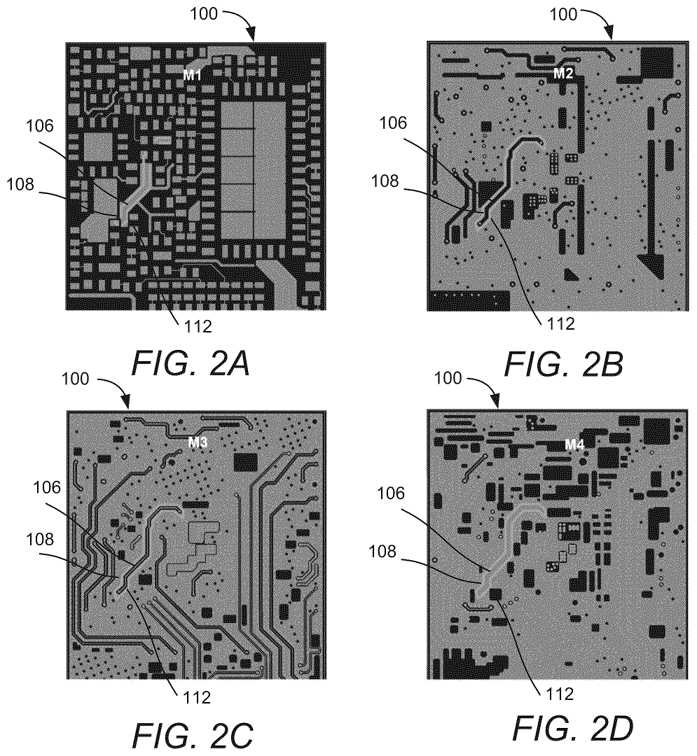

In an aspect, the IC device 100 in FIG. 1 may include a first continuous conductive shield 108 disposed along a first side 110 of the transmission line 106 and a second continuous conductive shield 112 disposed along a second side 114 opposite the first side 110 of the transmission line 106. In an aspect, the first continuous conductive shield 108 and the second continuous conductive shield 112 are formed by forming first and second trenches 116 and 118, respectively, within the PID 104, to the first and second sides 110 and 114 of the transmission line 106. In an aspect, the first and second trenches 116 and 118 may be metal filled to form RF shields on both the first and the second sides 110 and 114 of the transmission line, respectively. In an aspect, the first and second trenches 116 and 118 may be provided along the entire length of the transmission line 106, which will be illustrated in FIGS. 2A-2D for metal layers M1, M2, M3 and M4, described below.

Referring to FIG. 1, the first and second continuous conductive shields 108 and 112 may be provided across multiple metal layers, for example, from M1 layer 120 through M2 layer 122 and M3 layer 124 to M4 layer 126. In various implementations, the first and second continuous conductive shields 108 and 112 may be provided across different numbers of metal layers. In FIG. 1, the first and second continuous conductive shields 108 and 112 are shown as having the same width W. In various implementations, the first and second continuous conductive shields may not have an identical width.

In an aspect, the first and second continuous conductive shields 108 and 112 shield the transmission line 106 by reducing leakage of RF signals traveling along the transmission line 106 beyond a space 128 defined by the first and second continuous conductive shields 108 and 112.

FIGS. 2A-2D illustrate planar views of metal layers M1, M2, M3 and M4, respectively, of an IC device 100 according to aspects of the disclosure. FIG. 2A depicts a planar view of the first metal layer M1 according to an aspect. As shown in FIG. 2A, the first and second continuous conductive shields 108 and 112 may run substantially parallel to the transmission line 106 and disposed along substantially the entire length of the transmission line 106, although the transmission line 106 itself may not be visible in the planar view of the M1 layer if the transmission line 106 is not positioned on the M1 layer.

According to an aspect as shown in FIG. 2B, the first and second continuous conductive shields 108 and 112 as well as the transmission line 106 may be visible in the planar view of the M2 layer if the transmission line 106 is formed on the M2 layer. According to an aspect as shown in FIG. 2C, the first and second continuous conductive shields 108 and 112 as well as the transmission line 106 may be visible in the planar view of the M3 layer if the transmission line 106 is formed on the M3 layer. In various implementations, the transmission line 106 may be formed on the M2 layer, the M3 layer, or another metal layer within the scope of the disclosure. According to an aspect as shown in FIG. 2D, the first and second continuous conductive shields 108 and 112 are visible on the M4 layer, although the transmission line 106 itself may not be visible in the planar view of the M4 layer if the transmission line is not positioned on the M4 layer.

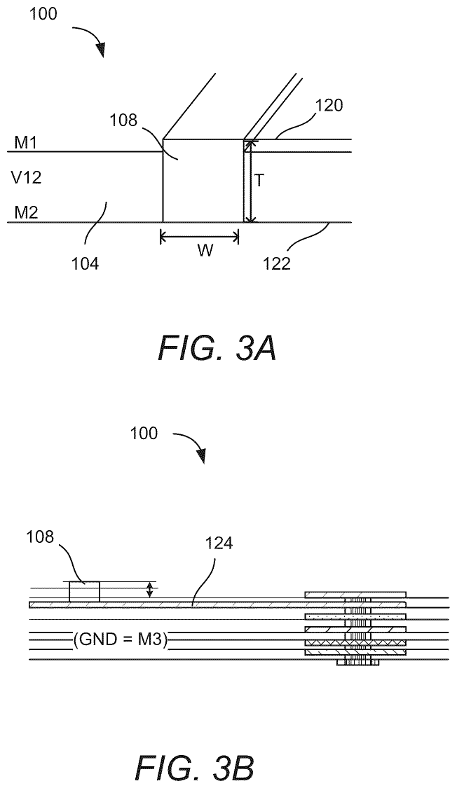

FIGS. 3A-3B illustrate cross-sectional views depicting an example of a continuous conductive shield formed across metal layers. As noted in the foregoing, the first continuous conductive shield 108 or the second continuous conductive shield 112 may each be formed across one or more metal layers within the scope of the disclosure. In the example shown in FIG. 3A, the first continuous conductive shield 108 is formed across the M1 layer 120 and the M2 layer 122. In various implementations, the first continuous conductive shield 108 may be formed across other metal layers in a similar manner. In an aspect, the second continuous conductive shield 112 may be formed in a similar manner to the first continuous conductive shield 108.

Referring to FIG. 3A, the first continuous conductive shield 108 may be formed by providing a metal filled trench within the PID 104. In an example implementation, the width W of first continuous conductive shield 108, that is, the width of the metal filled trench, may be approximately 60 μm. In an example implementation, the thickness T of the first continuous conductive shield 108 across the M1 and M2 layers 120 and 122 may be approximately 32 μm. In various implementations, the total thickness of the first continuous conductive shield 108 may span over multiple metal layers.

Referring to FIG. 3B, one of the metal layers, for example, the M3 layer 124, may be grounded. In an aspect, the first continuous conductive shield 108 may be in contact with the M3 layer 124 to ensure that the first continuous conductive shield 108 is grounded. In various implementations, another metal layer may be grounded in addition or as an alternative to the M3 layer 124.

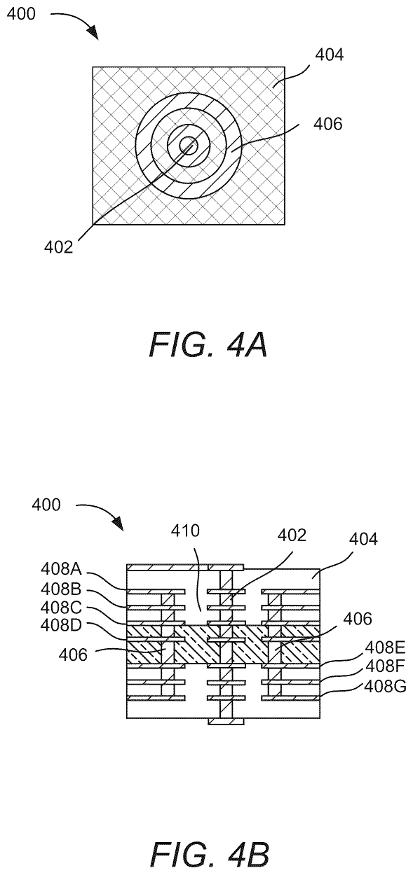

FIGS. 4A-4B illustrate top and cross-sectional views, respectively, of an IC device 400 having a trench shielded vertical transmission line. In FIGS. 4A-4B, a vertical transmission line 402 is provided within a PID 404. In an aspect, the vertical transmission line 402 may be formed by forming a via within the PID 404 and metal filling the via, for example. In an aspect, trench shielding may be provided to shield the vertical transmission line 402 from other parts of the IC device. In an aspect, a continuous conductive shield 406 formed by trench shielding may be provided as a cylindrical conductive shield that is concentric about the transmission line 402. In an aspect, the vertical transmission line 402 and the continuous conductive shield 406 may be formed across one or multiple metal layers, for example, metal layers 408A, 408B, 408C, 408D, 408E, 408F and 408G as depicted in FIG. 4B. In some aspects, one or more of the metal layers 408A, 408B, 408C, 408D, 408E, 408F and 408G may serve as a ground plane for the IC device 400.

In an aspect, the continuous conductive shield 406 shields the vertical transmission line 402 by reducing leakage of RF signals traveling along the vertical transmission line 402 beyond a space 410 defined by the continuous conductive shield 406.

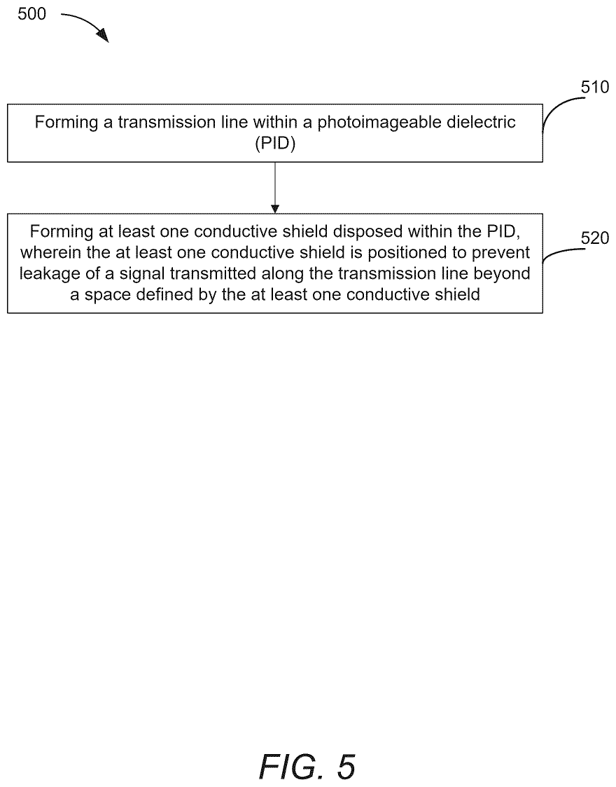

FIG. 5 illustrates a method 500 of manufacturing an IC device (for example, IC device 100 as shown in FIGS. 1, 2A-2D, 3A-3B and/or IC device 400 as shown in FIGS. 4A-4B), according to aspects of the disclosure.

At operation 510, a transmission line (e.g., transmission line 106 or 402) may be formed within a photoimageable dielectric (PID) (e.g., PID 104 or 404). In some aspects, the IC device 100 or 400 may be an RF IC device, an analog IC device, a mixed-signal IC device, a SOC IC device, or the like.

At operation 520, at least one continuous conductive shield (e.g., conductive shield 108, 112 or 406) is formed within the PID (e.g., PID 104 or 404), wherein the at least one continuous conductive shield (e.g., conductive shield 108, 112 or 406) is positioned to reduce leakage of a signal transmitted along the transmission line (e.g., transmission line 106 or 402) beyond a space (e.g., space 128 or 410) defined by the at least one continuous conductive shield (e.g., conductive shield 108, 112 or 406).

In some aspects, the method 500 may further include additional implementations, such as any single implementation or any combination of implementations described below and/or in connection with one or more other processes described elsewhere herein.

In some aspects, forming the transmission line may include forming a horizontal transmission line (e.g., transmission line 106) substantially in parallel with a ground plane (e.g., ground plane 102).

In some aspects, forming the at least one continuous conductive shield may include forming a first continuous conductive shield (e.g., conductive shield 108) along a first side (e.g., side 110) of the horizontal transmission line (e.g., transmission line 106) and a second continuous conductive shield along a second side (e.g., side 114) opposite the first side (e.g., side 110) of the horizontal transmission line (e.g., transmission line 106).

In some aspects, forming the first continuous conductive shield (e.g., conductive shield 108) and the second continuous conductive shield (e.g., conductive shield 112) may include forming first and second conductor-filled trenches along the first and second sides (e.g., sides 110 and 114) of the horizontal transmission line (e.g., transmission line 106), respectively.

In some aspects, forming the transmission line may include forming a vertical transmission line (402) substantially perpendicular to a ground plane (e.g., a metal layer such as 408A, 408B, 408C, 408D, 408E, 408F, or 408G).

In some aspects, forming the at least one continuous conductive shield may include forming a continuous conductive shield (e.g., conductive shield 406) surrounding the vertical transmission line (e.g., transmission line 402).

In some aspects, forming the continuous conductive shield surrounding the vertical transmission line may include forming a cylindrical conductive shield (e.g., conductive shield 406) concentric about the vertical transmission line (e.g., transmission line 402).

Although FIG. 5 shows example operations of a method 500, in some implementations, the method 500 may include additional operations, fewer operations, different operations, or differently arranged operations from those depicted in FIG. 5. Additionally, or alternatively, two or more of the operations of the method 500 may be performed in parallel, or may be performed in a temporal sequence different from the order listed or described.

A technical advantage of various aspects of the disclosure is that trench shielding of transmission lines in an IC device, including horizontal and vertical transmission lines, provides improved shielding of the transmission lines by significantly reducing undesired leakage of RF signals carried by the transmission lines to other parts of the IC device, as well as significantly reducing undesired interference by signals from other parts of the IC device with the RF signals carried by the transmission lines. In various aspects, trench shielding allows for better isolation of RF signals carried by the transmission lines from other parts of the IC device with less signal leakage than conventional methods of shielding, for example, via shielding. Also, by utilizing PID as a dielectric material surrounding the transmission line, trench shielding can be achieved with less technical difficulty and at a lower cost than attempting to provide continuous shielding through methods such as laser drilling or mechanical drilling, for example.

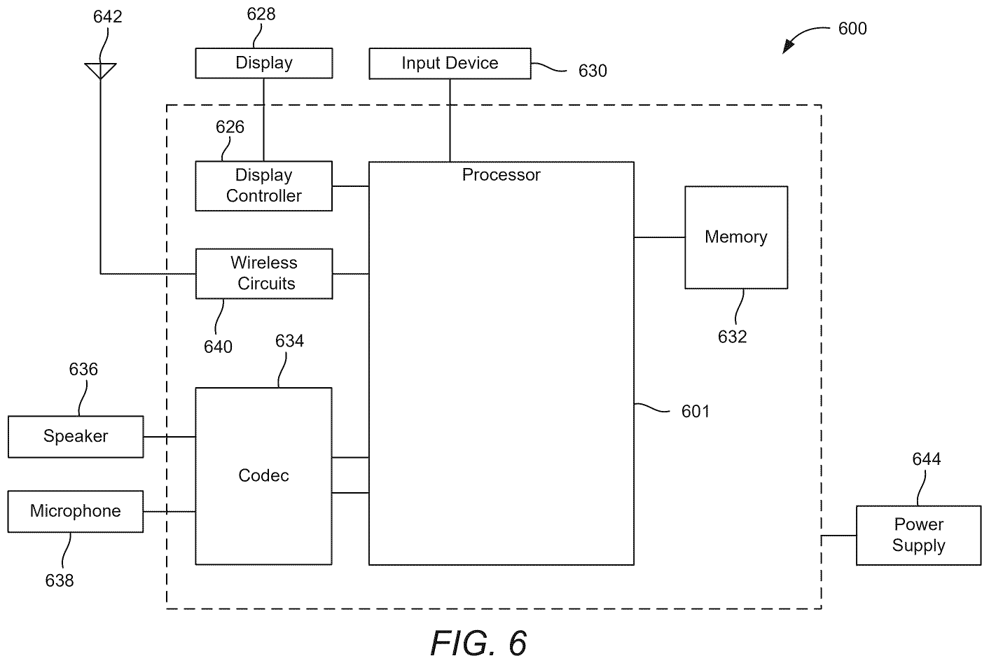

FIG. 6 illustrates a mobile device 600, according to aspects of the disclosure. In some aspects, the mobile device 600 may be implemented by including an IC device (e.g., IC device 100 or 400) disclosed herein.

In some aspects, mobile device 600 may be configured as a wireless communication device. As shown, mobile device 600 includes processor 601. Processor 601 may be communicatively coupled to memory 632 over a link, which may be a die-to-die or chip-to-chip link. Mobile device 600 also includes display 628 and display controller 626, with display controller 626 coupled to processor 601 and to display 628. The mobile device 600 may include input device 630 (e.g., physical, or virtual keyboard), power supply 644 (e.g., battery), speaker 636, microphone 638, and wireless antenna 642. In some aspects, the power supply 644 may directly or indirectly provide the supply voltage for operating some or all of the components of the mobile device 600.

In some aspects, FIG. 6 may include coder/decoder (CODEC) 634 (e.g., an audio and/or voice CODEC) coupled to processor 601; speaker 636 and microphone 638 coupled to CODEC 634; and wireless circuits 640 (which may include a modem, RF circuitry, filters, etc.) coupled to wireless antenna 642 and to processor 601.

In some aspects, one or more of processor 601 (e.g., SoCs, application processor (AP)), display controller 626, memory 632, CODEC 634, and wireless circuits 640 (e.g., baseband interface) including IC devices that are packaged as IC packages according to the various aspects described in this disclosure.

It should be noted that although FIG. 6 depicts a mobile device 600, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

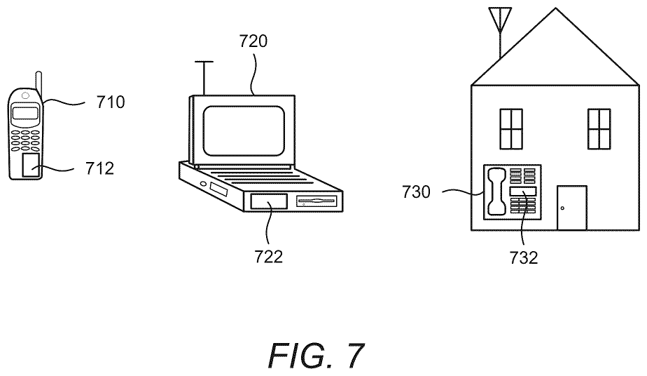

FIG. 7 illustrates various electronic devices 710, 720, and 730 that may incorporate IC devices 712, 722, and 732, which may include IC devices (e.g., IC devices 100 and/or 400) described herein, according to aspects of the disclosure.

For example, a mobile phone device 710, a laptop computer device 720, and a fixed location terminal device 730 may each be considered generally user equipment (UE) and may include one or more IC devices, such as IC devices 712, 722, and 732, and a power supply to provide the supply voltages to power the IC devices. The IC devices 712, 722, and 732 may be, for example, correspond to an IC device packaged as an IC package having a package substrate manufactured based on the examples described above with reference to FIGS. 1-6.

The devices 710, 720, and 730 illustrated in FIG. 7 are merely non-limiting examples. Other electronic devices may also feature the IC devices including package substrates as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-7 may be rearranged and/or combined into a single component, process, feature, or function or incorporated in several components, processes, or functions. Additional elements, components, processes, and/or functions may also be added without departing from the disclosure. In some implementations, FIGS. 1-7 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An integrated circuit (IC), comprising: a photoimageable dielectric (PID); a transmission line disposed within the PID; and at least one continuous conductive shield disposed within the PID, wherein the at least one continuous conductive shield is positioned to reduce leakage of a signal transmitted along the transmission line beyond a space defined by the at least one continuous conductive shield.

Clause 2. The IC of clause 1, wherein: the transmission line comprises a horizontal transmission line substantially in parallel with a ground plane.

Clause 3. The IC of clause 2, wherein: the at least one continuous conductive shield comprises a first continuous conductive shield disposed along a first side of the horizontal transmission line and a second continuous conductive shield disposed along a second side opposite the first side of the horizontal transmission line.

Clause 4. The IC of clause 3, wherein: the first and second continuous conductive shields are substantially parallel to the horizontal transmission line.

Clause 5. The IC of clause 4, wherein: the first and second continuous conductive shields are disposed along substantially an entire length of the horizontal transmission line.

Clause 6. The IC of any of clauses 3 to 5, wherein: the first and second continuous conductive shields are formed by first and second conductor-filled trenches along the first and second sides of the horizontal transmission line, respectively.

Clause 7. The IC of any of clauses 1 to 6, wherein: the transmission line comprises a vertical transmission line substantially perpendicular to a ground plane.

Clause 8. The IC of clause 7, wherein: the at least one continuous conductive shield comprises a continuous conductive shield surrounding the vertical transmission line.

Clause 9. The IC of clause 8, wherein: the continuous conductive shield comprises a cylindrical conductive shield concentric about the vertical transmission line.

Clause 10. The IC of clause 9, wherein: the cylindrical conductive shield is formed by a conductor-filled cylindrical trench concentric about the vertical transmission line.

Clause 11. A method of manufacturing an integrated circuit (IC), comprising: forming a transmission line within a photoimageable dielectric (PID); and forming at least one continuous conductive shield within the PID, wherein the at least one continuous conductive shield is positioned to reduce leakage of a signal transmitted along the transmission line beyond a space defined by the at least one continuous conductive shield.

Clause 12. The method of clause 11, wherein: forming the transmission line comprises forming a horizontal transmission line substantially in parallel with a ground plane.

Clause 13. The method of clause 12, wherein: forming the at least one continuous conductive shield comprises forming a first continuous conductive shield along a first side of the horizontal transmission line and a second continuous conductive shield along a second side opposite the first side of the horizontal transmission line.

Clause 14. The method of clause 13, wherein: forming the first continuous conductive shield and the second continuous conductive shield comprises forming first and second conductor-filled trenches along the first and second sides of the horizontal transmission line, respectively.

Clause 15. The method of any of clauses 11 to 14, wherein: forming the transmission line comprises forming a vertical transmission line substantially perpendicular to a ground plane.

Clause 16. The method of clause 15, wherein: forming the at least one continuous conductive shield comprises forming a continuous conductive shield surrounding the vertical transmission line.

Clause 17. The method of clause 16, wherein: forming the continuous conductive shield surrounding the vertical transmission line comprises forming a cylindrical conductive shield concentric about the vertical transmission line.

Clause 18. An electronic device, comprising: an integrated circuit (IC) that comprises: a photoimageable dielectric (PID); a transmission line disposed within the PID; and at least one continuous conductive shield disposed within the PID, wherein the at least one continuous conductive shield is positioned to reduce leakage of a signal transmitted along the transmission line beyond a space defined by the at least one continuous conductive shield.

Clause 19. The electronic device of clause 18, wherein: the at least one continuous conductive shield comprises a first continuous conductive shield disposed along a first side of the transmission line and a second continuous conductive shield disposed along a second side opposite the first side of the transmission line.

Clause 20. The electronic device of any of clauses 18 to 19, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. An integrated circuit (IC), comprising:
a photoimageable dielectric (PID);
a transmission line disposed within the PID; and
at least one continuous conductive shield disposed within the PID, wherein the at least one continuous conductive shield is positioned to reduce leakage of a signal transmitted along the transmission line beyond a space defined by the at least one continuous conductive shield.

2. The IC of claim 1, wherein:
the transmission line comprises a horizontal transmission line substantially in parallel with a ground plane.

3. The IC of claim 2, wherein:
the at least one continuous conductive shield comprises a first continuous conductive shield disposed along a first side of the horizontal transmission line and a second continuous conductive shield disposed along a second side opposite the first side of the horizontal transmission line.

4. The IC of claim 3, wherein:
the first and second continuous conductive shields are substantially parallel to the horizontal transmission line.

5. The IC of claim 4, wherein:
the first and second continuous conductive shields are disposed along substantially an entire length of the horizontal transmission line.

6. The IC of claim 3, wherein:
the first and second continuous conductive shields are formed by first and second conductor-filled trenches along the first and second sides of the horizontal transmission line, respectively.

7. The IC of claim 1, wherein:
the transmission line comprises a vertical transmission line substantially perpendicular to a ground plane.

8. The IC of claim 7, wherein:
the at least one continuous conductive shield comprises a continuous conductive shield surrounding the vertical transmission line.

9. The IC of claim 8, wherein:
the continuous conductive shield comprises a cylindrical conductive shield concentric about the vertical transmission line.

10. The IC of claim 9, wherein:
the cylindrical conductive shield is formed by a conductor-filled cylindrical trench concentric about the vertical transmission line.

11. A method of manufacturing an integrated circuit (IC), comprising:
forming a transmission line within a photoimageable dielectric (PID); and
forming at least one continuous conductive shield within the PID, wherein the at least one continuous conductive shield is positioned to reduce leakage of a signal transmitted along the transmission line beyond a space defined by the at least one continuous conductive shield.

12. The method of claim 11, wherein:
forming the transmission line comprises forming a horizontal transmission line substantially in parallel with a ground plane.

13. The method of claim 12, wherein:
forming the at least one continuous conductive shield comprises forming a first continuous conductive shield along a first side of the horizontal transmission line and a second continuous conductive shield along a second side opposite the first side of the horizontal transmission line.

14. The method of claim 13, wherein:
forming the first continuous conductive shield and the second continuous conductive shield comprises forming first and second conductor-filled trenches along the first and second sides of the horizontal transmission line, respectively.

15. The method of claim 11, wherein:
forming the transmission line comprises forming a vertical transmission line substantially perpendicular to a ground plane.

16. The method of claim 15, wherein:
forming the at least one continuous conductive shield comprises forming a continuous conductive shield surrounding the vertical transmission line.

17. The method of claim 16, wherein:
forming the continuous conductive shield surrounding the vertical transmission line comprises forming a cylindrical conductive shield concentric about the vertical transmission line.

18. An electronic device, comprising:
an integrated circuit (IC) that comprises:
a photoimageable dielectric (PID);
a transmission line disposed within the PID; and
at least one continuous conductive shield disposed within the PID, wherein the at least one continuous conductive shield is positioned to reduce leakage of a signal transmitted along the transmission line beyond a space defined by the at least one continuous conductive shield.

19. The electronic device of claim 18, wherein:
the at least one continuous conductive shield comprises a first continuous conductive shield disposed along a first side of the transmission line and a second continuous conductive shield disposed along a second side opposite the first side of the transmission line.

20. The electronic device of claim 18, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
